(19) United States
(12) Patent Application Publication
(10) Pub. No.: US 2010/0032011 A1
(43) Pub. Date: Feb. 11, 2010

(54) BACK CONTACTED SOLAR CELL

(76) Inventor: Erik SAUAR, Oslo (NO)

Correspondence Address: BIRCH STEWART KOLASCH & BIRCH, PO BOX 747, FALLS CHURCH, VA, 22040-0747, US

(21) Appl. No.: 12/443,281

(22) PCT Filed: Sep. 27, 2007
(86) PCT No.: PCT/NO2007/000339

§ 371 Date: May 28, 2009

Related U.S. Application Data
(60) Provisional application No. 60/848,010, filed on Sep. 29, 2006.

(30) Foreign Application Priority Data
Nov. 9, 2006 (GB) 0622393.7

(51) Int. Cl. H01L 31/02

(52) U.S. Cl. 136/256; 438/98; 257/E31.11

(57) ABSTRACT

This invention relates to a cost effective method of producing a back contacted silicon solar cell and the cell made by the method, where the method comprises applying a silicon substrate, wafer or thin film, doped on the back side with alternating P-type and N-type conductivity in an interdigitated pattern and optionally a layer of either P- or N-type on the front side of the wafer, depositing one or more surface passivation layers on both sides of the substrate, creating openings in the surface passivation layers on the back side of the substrate, depositing a metallic layer covering the entire back side and which fills the openings in the surface passivation layers, and creating openings in the deposited metallic layer such that electric insulated contacts with the doped regions on the back side of the substrate is obtained.

This invention relates to a cost effective method of producing a back contacted silicon solar cell and the cell made by the method.

### INTRODUCTION

The world supplies of fossil oil are expected to be gradually exhausted in the following decades. This means that our main energy source for the last century will have to be replaced within a few decades, both to cover the present energy consumption and the coming increase in the global energy demand.

In addition, there are raised many concerns that the use of fossil energy is increasing the earth greenhouse effect to an extent that may turn dangerous. Thus the present consumption of fossil fuels should preferably be replaced by energy sources/carriers that are renewable and sustainable for our climate and environment.

One such energy source is solar light, which irradiates the earth with vastly more energy than the present and any foreseeable increase in human energy consumption. However, solar cell electricity has up to date been too expensive to be competitive with nuclear power, thermal power etc. This needs to change if the vast potential of the solar cell electricity is to be realised.

The cost of electricity from a solar panel is a function of the energy conversion efficiency and the production costs of the solar panel. Thus the search for cheaper solar electricity should be focused at high-efficient solar cells made by cost-effective manufacturing methods.

### OBJECTIVE OF THE INVENTION

The main objective of the invention is to provide a cost-effective manufacturing method of high-efficient back-contacted solar cells.

A further objective of the invention is to provide a back-contacted solar cell with a high energy conversion rate.

The objectives of the invention may be realised by the features as set forth in the description of the invention below, and/or in the appended patent claims.

### DESCRIPTION OF THE INVENTION

The invention relates to the choice of passivation layers and how to obtain the electrical contact with the doped regions of the wafer underlying the passivation layers. Thus the invention may employ any silicon wafer or thin film which is doped such that the wafer may be back-contacted. This includes wafers or thin films of mono-, micro-, and multi-crystalline silicon and any known and conceivable configuration of the P and N doped regions on the back side of the wafer. There may also be an optional P or N doped layer on the front side of the wafer.

The term “front side” denotes the side of the solar wafer that is exposed to the sunlight. The term “back side” is the opposite side of the front side of the wafer, and the term “back-contacted” means that all connectors are placed on the back side of the solar wafer. The term “P-doped region” means a surface area of the wafer where a doping material resulting in an increased number of positive charge carriers is added into the silicon matrix within a certain distance below the surface forming a region of the wafer with a surface layer with P-type conductivity. The term “N-doped region” means a surface area of the wafer where a doping material resulting in increased number of negative charge carriers (mobile electrons) is added into the silicon matrix within a certain distance below the surface forming a region of the wafer with a surface layer with N-type conductivity.

Wafers for back-contacted solar cells should have at least one region of each type conductivity P and N on its back side, but typically there will be several doped regions with alternating conductivity in an interdigitated pattern. The wafer may also have a doped layer on the front side of one of the P- or N-type conductivity. The front-side doped layer is optional.

The invention may apply any known method for doping or manufacturing the layers with the one or other type of conductivity. At the front surface of the solar cell, an optional layer of the one or the other type conductivity may be prepared by in-diffusion from a liquid, solid or gaseous source. The manufacturing of the layer of alternating conductivity may be by simultaneous or consecutive in-diffusion of dopants by the use of laser doping, by ink-jetting and annealing of different dopant sources or by screen printing and annealing of different dopant sources. A low cost method for obtaining the alternating layer is first to apply the dopant sources for the one and the other type of conductivity on the wafer by use of ink-jet printing in one apparatus equipped with two dopant sources, and then simultaneously prepare the dopant layer by in-diffusion at elevated temperatures.

The invention may employ any known surface passivation at the front side of the wafer, and it may be employed any known method for forming the passivation layers. However, the invention is linked to the choice of the first passivation layer on the back side of the wafer and how to obtain the electrical contact with the P- and N-type doped regions below the first passivation layer. Thus an especially cost effective and high-efficient solar cell is obtained if one employs the double passivation layer structure known from the applicant's PCT-application WO2006/110048 A1 on both the front and back side of the wafer, then forming openings in the outer passivation layer on the back side of the wafer, followed by deposition of a metallic phase on the entire back side of the wafer, annealing the passivation layers as described in WO2006/110048 A1 and simultaneously obtain that the metallic phase in the openings creates contact with the P- and N-type doped regions underlying the first passivation layer, and finally creating openings/free regions in the deposited metallic layer to create electric insulated contacts with each doped region on the back side of the wafer.

The preferred double passivation layer structure disclosed in WO2006/110048 A1 comprises a first hydrogenated amorphous silicon or hydrogenated amorphous silicon carbide thin film of thickness in the range of 1-150 nm which is deposited onto the doped layers on both sides of the silicon wafer, followed by depositing a hydrogenated silicon nitride thin film of thickness in the range of 10-200 nm atop the amorphous silicon or amorphous silicon carbon layer on both sides of the wafer. Both the amorphous silicon or silicon carbide and silicon nitride films may be deposited by plasma enhanced chemical vapour deposition (PECVD). The two films may be deposited in a substantially single or multiple deposition process. Examples of further methods for deposition of the one or more passivation layer(s) include, but are not limited to; plasma enhanced chemical vapour deposition, hot wire chemical vapour deposition, low temperature chemical vapour deposition, low pressure chemical vapour deposition, or sputtering.

Alternatively, at the front surface, the amorphous silicon layer may be replaced by a thin layer of silicon oxide prepared by thermal oxidation, sputtering or plasma enhanced vapour deposition.

The invention may employ any known method for creating openings in the one or more passivation layer(s). This may include etching techniques where a chemical agent dissolves the passivation layer(s) at specified local areas on at least one surface of the solar wafer. The etching agent may be applied by ink-jet printing or screen-printing, alternatively the localized etching may be obtained by ink-jet printing or screen-printing a chemical resist followed by complete or partly immersion of the solar wafer in an etching fluid, etc. The chemical etching agent may consist of, but are not limited to, diluted or concentrated HF, KOH, NaOH, or a mixture comprising HF, HNO₃, and CH₃COOH. An alternative method of obtaining the openings in the passivation layer(s) may be localised heating burning the passivation layer away, for instance by exposure to a laser beam.

In case of employing the preferred dual passivation layer described in WO2006/110048 A1, the removal of the passivation layers may only be applied for the outer silicon nitride layer. The underlying amorphous silicon layer or amorphous silicon carbide layer should be intact. Alternatively, it may be created openings in all passivation layers such that the following deposition of the metallic layer obtains direct contact with the underlying doped regions of the wafer.

The deposition of the metallic layer may be obtained by for instance electroless plating or electroplating of nickel, silver, copper, and/or tin, or any combination of these materials. The invention is not restricted to these choices of metals, it may apply any material that provides a good electric contact with the underlying silicon substrate and which is resistant towards UV-light, temperatures up to about 150-250° C. and any other disruptive force/physical condition associated with normal use of solar panels during the expected lifetime of a solar panel and of subsequent manufacturing steps after formation of the contacts. This may include known electric conducting plastics and/or other polymer formulations such as carbon polymers, etc. It is not given any restriction on the required electric conductance of the material employed for forming the contacts, since this requirement is strongly dependent upon the geometry and dimensions of the solar cells/panels that is to be contacted and a skilled person will know which conductivity which is required.

In case of employing the preferred dual passivation layer described in WO2006/110048 A1, a well suited metallic layer is aluminium. The aluminium layer should have a thickness in the range of approximately 1-50 μm depending upon cell size and design, and may be deposited by sputtering or evaporation of an aluminium layer at temperatures from about room temperature to about 200° C. covering the whole second surface, or by screen printing of an aluminium based metal paste covering the whole second surface. In the case of screen printing an aluminium containing paste, it is understood the use of commercial thick film pastes containing aluminium particles and that may or may not contain glass particles, followed by a bake-out of any organic solvents at temperatures <400° C. After deposition of the aluminium layer, the contacting and simultaneous optimization of the passivation effect is obtained by heating the wafer to a temperature in the range of 300-600° C., preferably to about 500° C. for four minutes. See WO2006/110048 A1 for further details.

After formation of the electric contacts with the doped regions on the back side of the wafer, the continuous metallic layer must be divided into an electric insulated region for each doped region. This may be obtained by removing the deposited metallic layer in a specific pattern, by for example ink-jetting of an etching agent, or by ink-jetting of a chemical resist followed by a single sided etching. The pattern for etching of the aluminium is selected such that two distinct contact regions appear on the metallic layer after the etching, one contact region for the P-type doped regions and one for the N-type doped regions.

### EXAMPLE OF THE INVENTION

The invention will be described by way of an example of a preferred embodiment of a method for manufacturing a back-contacted solar cell with high energy conversion efficiency and a preferred embodiment of a solar cell made by the inventive method.

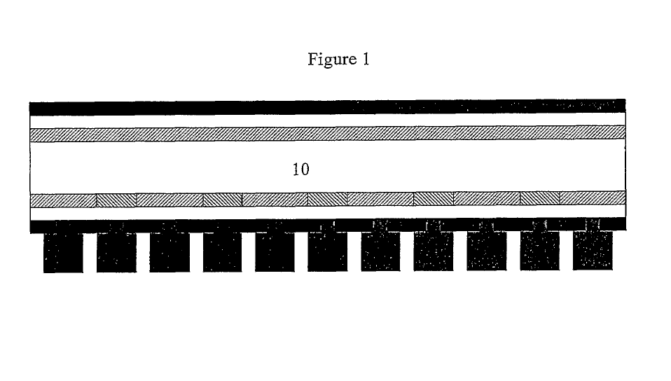

The preferred embodiment of the solar cell is illustrated in FIG. 1. A silicon wafer 1 is on the front side covered by a doped layer 2 of P- or N-type conductivity. On the back side, the silicon wafer 1 is covered by a layer 3 with alternating conductivity in an interdigitated pattern. On top of layer 2 there is deposited a thin layer 4 of amorphous silicon or silicon oxide, and a layer 5 of silicon nitride is deposited outside layer 4. On the back side, the layer 3 of alternating conductivity is covered by a layer 6 of amorphous silicon or amorphous silicon carbide and then a layer 7 of silicon nitride with at least one opening 8 for each doped region in layer 3. On top of the silicon nitride layer 7, there is deposited a layer 9 of aluminium which fills the openings 8 in the silicon nitride layer 7. After annealing, the aluminium in the openings 8 have created re-crystallised regions 10 in the underlying amorphous silicon layer 6 and thus created electric contact with the doped region in layer 3 below. Then the aluminium layer 9 is divided into electric insulated zones by creating openings 11 in the layer 9.

The preferred method for manufacturing the preferred embodiment comprises:

applying a silicon wafer doped on the back side with alternating P-type and N-type conductivity in an interdigitated pattern and optionally a layer of either P- or N-type on the front side of the wafer,

depositing a layer of amorphous silicon or amorphous silicon carbide on both sides of the doped wafer followed by deposition of a layer of silicon nitride layer on top of the amorphous silicon layer on both sides of the wafer,

creating openings in the silicon nitride layer to expose the underlying amorphous silicon nitride layer on the back side of the wafer,

depositing an aluminium layer covering the entire back side of the wafer,

heating the wafer to a temperature in the range of 200 to 700° C., preferably 300-600° C. to obtain electric contact between the aluminium layer and underlying doped regions of the silicon wafer, and

creating openings in the aluminium layer to isolate the contacts from each doped region on the back side of the wafer.

The surface passivation in this case is obtained as follows: The wafers (1) are cleaned by immersion in a mixture of H₂SO₄ and H₂O₂, a mixture of HCl, H₂O₂ and H₂O, or a mixture of NH₄OH, H₂O₂ and H₂O, followed by an oxide removal in diluted HF. Then the wafers are introduced into a plasma enhanced chemical vapour deposition chamber (PECVD-chamber), and the amorphous silicon film with thickness 1-150 nm, preferably around 10-100 nm is deposited by use of SiH₄ as sole precursor gas. The amorphous silicon film is deposited on both surfaces of the wafers and is denoted by reference number 4 and 6 of the front and back side of the wafer, respectively. Alternatively, there may be deposited a silicon carbide film. Then a layer of silicon nitride is deposited by use of a mixture of SiH₄ and NH₃ as precursor gases in the PECVD-chamber. The thickness of the silicon nitride film should be in the range of 10-200 nm, preferably around 70-100 nm. The precursor gases may also comprise from 0 to 50 mol % hydrogen gas. The silicon nitride film is deposited on both sides of the wafers and is denoted by reference numbers 5 and 7 on the front and back side of the wafer, respectively. The deposition temperature in the PECVD-chamber is about 250° C. for both films.

Studies by the inventors show that the best mode of the passivation layers is a 10-100 nm amorphous silicon and a 70-100 nm silicon nitride that is annealed at 500° C. A dual 80 nm amorphous silicon and 100 nm silicon nitride film gives an effective recombination lifetime on a silicon wafer of 0.0007 s, depending on the recombination time of the bulk material, which is about 1 order of magnitude better than single films of amorphous silicon or silicon nitride, or 2-3 times higher than a dual film of amorphous silicon and silicon nitride that is not annealed. Without being bound by theory, the reason for the markedly increased passivation effect is believed to be due to diffusion of hydrogen atoms into the boundary region of the crystalline silicon substrate which satisfies dangling bonds in the crystalline silicon. Measurements of the hydrogen content in the surface layers of the silicon wafer after annealing temperature at about 500° C. shows that the silicon phase contains about 10 atom % H. Annealing at higher or lower temperatures gives lesser hydrogen contents.

The openings in the passivation layer(s) on the back side of the wafer are obtained by ink-jet printing a chemical etching agent comprising a solution diluted or concentrated HF, KOH, NaOH, or a mixture comprising HF, HNO₃, and CH₃COOH, or a combination thereof. The choice of method for obtaining the openings is not important. The vital feature is that the passivation layer 7 must be locally removed to expose the underlying amorphous silicon layer 6, or alternatively both layers 6, 7 must be locally removed to expose the doped regions 3 of the wafer 1.

The passivation procedures is finalised by heating the wafers to a temperature in the range of 300-600° C., preferably around 500° C. for four minutes. This annealing may advantageously be performed after deposition of the aluminium layer 9.

The aluminium layer should have a thickness in the range of approximately 1-50 μm, and may be deposited by sputtering or evaporation of an aluminium layer at temperatures from about room temperature to about 200° C. covering the whole second surface, or by screen printing of an aluminium based metal paste covering the whole second surface. In the case of screen printing a aluminium containing paste, it is understood the use of commercial thick film pastes containing aluminium particles and that may or may not contain glass particles, followed by a bake-out of any organic solvents at temperatures <400° C.

The openings in the aluminium layer may be obtained by use of ink-jet printing of an etching agent able to remove the metallic layer, but not the underlying silicon nitride layer. In case of making holes in an aluminium layer, hydrochloric acid may be employed as etching agent. Any acid or base known to dissolve the metallic phase, but not the underlying passivation layer may be employed as etching agent. As an alternative there may be ink-jet printed a resist mask followed by immersion of the wafer in an etching liquid.

1-16. (canceled)

17. Method for producing a back-contacted solar cell, where the method comprises applying a silicon substrate, wafer or thin film, doped on the back side with alternating P-type and N-type conductivity in an interdigitated pattern and optionally a layer of either P- or N-type on the front side of the wafer,
wherein the method further comprises:
depositing one or more surface passivation layers on the front side and on the back side of the substrate,
the surface passivation layer on the back side comprises an inner amorphous silicon layer or an amorphous silicon carbide layer, the inner layer is followed by a layer of hydrogenated silicon nitride,
creating openings in one or more surface passivation layers on the back side of the substrate,
depositing a metallic layer covering substantially all of the back side and which fills the openings in the surface passivation layers,
creating openings in the deposited metallic layer such that electrically insulated contacts with the doped regions on the back side of the substrate is obtained.

18. Method according to claim 17,
wherein
the openings in the surface passivation layers is only made in the outer silicon nitride layer (7).

19. Method according to claim 17,
wherein
the metallic layer is substantially aluminium or substantially nickel.

20. Method according to claim 17,
wherein
the substrate is heated to a temperature the range of 200-700° C., preferably in the range of 300-600° C.

21. Method according to claim 18,
wherein
the inner amorphous silicon layer on the back side of the substrate has a thickness in the range of 1-1000 nm,
the surface passivation layer on the front side comprises an outer silicon nitride layer, said silicon nitride layer has a thickness in the range of 10-200 nm,
the outer hydrogenated silicon nitride layer on the back side of the substrate has a thickness in the range of 10-1000 nm.

22. Method according to claim 20,
wherein
the aluminium layer has a thickness in the range of 1-50 μm and is deposited by use of sputtering or evaporation, and
the following heat treatment is performed at a temperature about 500° C. for four minutes.

23. Method according to claim 17,
wherein the openings in the surface passivation layers are obtained by:
use of an etching agent that is either ink-jet printed or screen-printed onto the region(s) of the outer surface passivation layer on the back side of the substrate,
use of laser to ablate the surface passivation layers, or
screen-printing or ink jet printing a chemical resist covering the areas of the surface passivation layer that are to remain on the back side of the substrate and optionally screen-printing or ink jet printing a chemical resist covering the entire front surface passivation of the substrate followed by at least partial immersion of the substrate in an etching agent to remove the unprotected passivation film(s).

24. A method according to claim 23,
wherein
the chemical etching agent comprises one or more of the following agents; a solution comprising diluted or concentrated HF, or KOH, or NaOH, or a mixture comprising HF, HNO₃, and CH₃COOH.

25. A method according to claim 21,
wherein the surface passivation of the front and back side of the semiconductor substrate is obtained by:
cleaning the semiconductor substrate by immersion in a mixture of H₂SO₄ and H₂O₂, or a mixture of HCl, H₂O₂ and H₂O, or a mixture of NH₄OH, H₂O₂ and H₂O, removing the oxide film on the substrate sides by immersion in diluted HF,
introducing the substrate into a plasma enhanced chemical vapour deposition chamber (PECVD-chamber), —depositing a 1-150 nm thick amorphous silicon film on one or both sides of the substrate by use of SiH₄ as sole precursor gas at about 250° C.,
depositing a 10-200 nm thick silicon nitride film by use of a mixture of SiH₄ and NH₃ as precursor gases at about 250° C. on top of the one or both amorphous silicon films, and finally
annealing the substrate with the deposited passivation at a temperature about 500° C. for four minutes.

26. A method according to claim 25,
wherein the annealing is performed after deposition of the metallic layer on top of the silicon nitride layer on the back side of the substrate.

27. A solar cell comprising:
a silicon substrate (1) doped in a layer (3) on the back side with alternating P-type and N-type conductivity in an interdigitated pattern and optionally a layer (2) of either P- or N-type on the front side of the substrate (1),
one or more surface passivation layers (4, 5) on the front side of the substrate (1), wherein it further comprises:
one or more surface passivation layers (6,7) on the back side of the substrate (1),
the inner surface passivation layer (6) is an amorphous silicon layer or an amorphous silicon carbide layer, the inner layer is followed by a layer of hydrogenated silicon nitride,
at least one opening (8) in one or more surface passivation layers (6, 7) for each doped region of the layer (3), and
a metallic contact (9) filling each opening (8) to obtain electric contact with the underlying doped region in the layer (3) of the substrate (1).

28. Solar cell according to claim 27,
wherein
the metallic layer is substantially aluminium or substantially nickel.

29. Solar cell according to claim 27,
wherein
the inner amorphous silicon layer on the back side of the substrate has a thickness in the range of 1-1000 nm,
the surface passivation layer on the front side comprises an outer silicon nitride layer, said silicon nitride layer has a thickness in the range of 10-200 nm,
the outer hydrogenated silicon nitride layer on the back side of the substrate has a thickness in the range of 10-1000 nm.

30. Solar cell according to claim 27,
wherein
the metallic contacts (9) have a thickness as measured perpendicular on the surface passivation layers in the range of 1-50 μm.

31. Solar cell according to claim 27,
wherein
the openings (8) in the surface passivation layers has only been made in the outer surface passivation layers (7) on the back side of the substrate (1), and
the electric contact with the doped regions below the amorphous silicon layer (6) is obtained by heating the substrate until the aluminium phase (8) re-crystallises the in-between lying amorphous silicon layer (6) and forms connection points (10).

32. Solar cell according to claim 17,
wherein the substrate (1) is either a mono-crystalline, micro-crystalline, or a multi-crystalline silicon wafer, or a silicon thin film of either micro crystalline, multi crystalline or mono crystalline grain quality.

33. Method according to claim 18,
wherein
the metallic layer is substantially aluminium or substantially nickel.

34. Method according to claim 18,
wherein
the substrate is heated to a temperature the range of 200-700° C., preferably in the range of 300-600° C.

35. Method according to claim 19,
wherein
the substrate is heated to a temperature the range of 200-700° C., preferably in the range of 300-600° C.

36. Method according to claim 19,
wherein
the inner amorphous silicon layer on the back side of the substrate has a thickness in the range of 1-1000 nm,
the surface passivation layer on the front side comprises an outer silicon nitride layer, said silicon nitride layer has a thickness in the range of 10-200 nm,
the outer hydrogenated silicon nitride layer on the back side of the substrate has a thickness in the range of 10-1000 nm.
